(19) United States
(12) Patent Application Publication
(10) Pub. No.: US 2008/0297184 A1
(43) Pub. Date: Dec. 4, 2008

(54) SEMICONDUCTOR TEST APPARATUS

(75) Inventors: Kiyotoshi MIURA, Aomori (JP); Tatsuo INOUE, Tokyo (JP); Kenichi WASHIO, Kanagawa (JP)

Correspondence Address: INGRASSIA FISHER & LORENZ, P.C., 7010 E. COCHISE ROAD, SCOTTSDALE, AZ, 85253, US

(73) Assignee: KABUSHIKI KAISHA NIHON MICRONICS, Tokyo (JP)

(21) Appl. No.: 12/105,581

(22) Filed: Apr. 18, 2008

(30) Foreign Application Priority Data
May 30, 2007 (JP) 2007-143060

(51) Int. Cl. G01R 1/073

(52) U.S. Cl. 324/754

(57) ABSTRACT

The present invention provides a semiconductor test apparatus that can reduce influence of noise in high-frequency measurement and that can be manufactured inexpensively by simplification of the constitution. A semiconductor test apparatus according to the present invention is one for use in an electrical test of a semiconductor wafer in which numerous integrated circuits each having electrode pads are incorporated. It comprises a probe card and a tester having a connection portion to the probe card. The probe card has numerous probes that can be connected to the electrode pads of the semiconductor wafer and a probe board having on one surface probe lands to which the probes are attached, having on the other surface tester lands corresponding to the probes, and having wiring paths each connecting the probe land and the tester land corresponding to each other. The tester is directly connected to the probe card as the connection portion contacts the tester lands.

### BACKGROUND OF THE INVENTION

The present invention relates to a semiconductor test apparatus for use in an electrical test of a semiconductor wafer in which numerous integrated circuits are incorporated.

In an electrical test of numerous integrated circuits incorporated in a semiconductor wafer is generally used a test apparatus comprising a tester and a probe card provided with numerous probes that connect the tester to respective electrode pads of the integrated circuits as devices under test (for example, refer to Patent Document 1).

A test apparatus 1 of this kind comprises a probe card 4 provided with probes 4a that can be connected to electrode pads of a semiconductor wafer 3 as a device under test held on a chuck 2a of a prober apparatus 2, as shown in FIG. 8.

The probe card 4 is opposed to the lower surface of a wiring board 5 and is attached to the wiring board. Also, the edge portion of the probe card 4 is held by the wiring board 5 via an annular holding tool 6. The wiring board 5 projects from a probe board 4b of the probe card 4 so that its edge portion is mounted on a holder portion 2c of a casing 2b of the prober apparatus 2 and is attached to the holder. In this manner, the probe card 4 is held by the casing 2b via the wiring board 5.

The respective probes 4a are connected to corresponding wiring paths 7 provided in the probe board 4b. In the wiring board 5, wiring paths 7 corresponding to the wiring paths 7 of the probe board 4b are provided, and the both wiring paths 7, 7 of the wiring board 5 and the probe card 4 corresponding to each other are electrically connected to each other via a connector 8a such as a pogo pin assembly inserted between the portions 4 and 5.

On the upper surface of the wiring board 5 is provided an entirely annular reinforcement member 8b. Also, at the circumferential area on the upper surface of the wiring board 5 exposed from the reinforcement member 8b are provided tester lands 5a to be connected to connection portions 9a of a tester (test head) 9. Each probe 4a is connected to the tester 9 via the corresponding wiring path 7 of the probe board 4b, connector 8a, wiring path 7 of the wiring board 5, and tester land 5a.

Accordingly, when each probe 4a of the probe card 4 abuts on each corresponding electrode pad of the device under test 3 on the chuck 2a, the device under test 3 is connected to the tester 9, and an electrical test is conducted by the tester.

Patent Document 1: Japanese Patent Appln. Public Disclosure No. 2007-64850

### BRIEF SUMMARY OF THE INVENTION

However, in the conventional test apparatus 1, the connector 8a and the wiring board 5 constituting a probe assembly together with the probe card 4 exist between the probe card 4 provided with the probes 4a that can abut on the electrode pads of the device under test 3 and the tester 9. Thus, the constitution of the probe assembly including the probe card 4 is complicated. Moreover, since the connector 8a and the wiring board 5 exist therebetween, each circuit length from the tester 9 to the probe 4a is relatively long. Also, since the respective wiring paths 7 of the connector 8a and the wiring board 5 constituting this circuit are formed to be close to one another in response to a fine-pitch trend of the integrated circuits, the electrical test of the device under test 3 by the tester 9 with use of high frequency may be influenced by noise significantly. To deal with noise, shortening of the circuit length is effective.

It is an object of the present invention to provide a semiconductor test apparatus that can reduce influence of noise in high-frequency measurement and that can be manufactured inexpensively by simplification of the constitution.

Basically, the present invention is characterized by eliminating a wiring board and an electrical connector arranged between a tester and a probe card and directly connecting an electrical connection portion of the tester to the probe card.

More specifically, a semiconductor test apparatus according to the present invention is one for use in an electrical test of a semiconductor wafer in which numerous integrated circuits each having electrode pads are incorporated, and comprises a probe card and a tester having a connection portion to the probe card. The probe card has numerous probes that can be connected to the electrode pads of the semiconductor wafer and a probe board, and the probe board has on one surface the probes, has on the other surface tester lands corresponding to the probes, and has wiring paths each connecting the probe and the tester land corresponding to each other. The tester is directly connected to the probe card as the connection portion contacts the tester lands.

With the test apparatus according to the present invention, by directly connecting the electrical connection portion of the tester to the probe card, a connector and a wiring board conventionally provided between the tester and the probe board can be eliminated, and eliminating these can simplify the constitution of the test apparatus, which enables cost reduction. Also, by shortening the circuit length from the tester to the probe board, resistance to high-frequency noise is improved, and accuracy of a test using high-frequency signals can be heightened.

On one surface of the probe board may be provided probe lands connected to the corresponding tester lands via the wiring paths, and the probes may be connected to the probe lands.

The test apparatus may further comprise a prober mechanism. As the prober mechanism, a prober mechanism similar to a conventionally well-known wafer prober having a casing and a test stage provided with a chuck that holds the semiconductor wafer in the casing may be used. At the upper portion of the casing of this wafer prober may be provided an annular card holder for holding the probe board. Also, on the other surface of the probe board may be provided a support member provided with an edge portion projecting from an edge portion of the probe board and mounted on the card holder. In this manner, the probe card can be supported by the card holder via the support member so that the probes can abut on the electrode pads of the semiconductor wafer on the chuck.

As the support member, a support member having an annular rim portion having the edge portion mounted on the card holder, a boss portion located at the center of the annulus of the annular portion, and spoke portions coupling the boss portion with the rim portion may be used.

In this case, the tester lands are arranged at areas exposed from the support member on the other surface of the probe board.

Also, the tester lands may be arranged inside the annular rim portion. Since this can shorten the circuit length from each probe generally arranged at the center part of the probe board in a concentrated manner to the tester land, it is particularly effective to deal with high-frequency noise.

The probe board may consist of a ceramic plate and a multilayer wiring layer fixed on one surface of the ceramic plate. In this case, the wiring path of the probe board may consist of a wiring path part formed to pass through the ceramic plate in its plate thickness direction and a wiring path part of the multilayer wiring layer connected to the wiring path part. Also, the tester lands are formed on the other surface of the ceramic plate, and the probes are fixed on an opposite surface of a surface of the multilayer wiring layer fixed to the ceramic plate.

The connection portion of the tester may be formed by a pogo pin assembly fixed to a tester head.

According to the present invention, as described above, by directly connecting the electrical connection portion of the tester to the probe card, the constitution of the test apparatus can be simplified, and cost reduction is enabled. Also, by shortening the circuit length from the tester to the probe board, resistance to high-frequency noise is improved, and accuracy of a test using high-frequency signals can be heightened.

### BRIEF DESCRIPTION OF THE DRAWINGS

FIG. 1 is a schematic view showing a test apparatus according to the present invention.

FIG. 2 is a plan view of the test apparatus shown in FIG. 1.

FIG. 3 is a cross-sectional view obtained along the line III-III shown in FIG. 2.

FIG. 4 is an enlarged cross-sectional view showing a lock mechanism shown in FIG. 3.

FIG. 5 is a cross-sectional view showing the lock mechanism shown in FIG. 4 in a release state.

FIG. 6 is an enlarged cross-sectional view showing a screw coupling mechanism shown in FIG. 3.

FIG. 7 is a cross-sectional view obtained along the line VII-VII shown in FIG. 2.

FIG. 8 is a schematic view showing a conventional test apparatus.

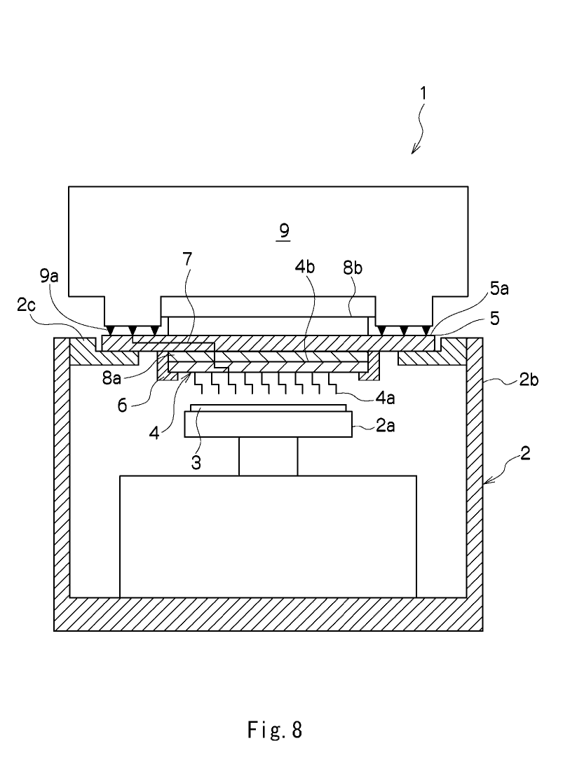

### DETAILED DESCRIPTION OF THE INVENTION

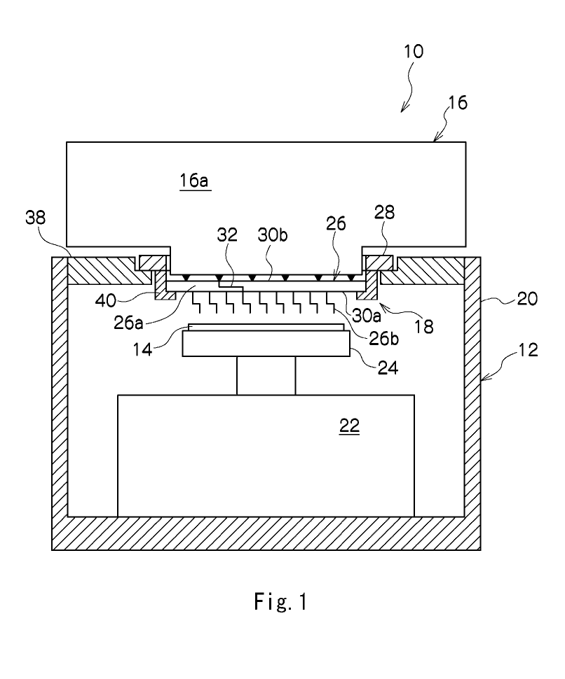

A test apparatus 10 according to the present invention comprises a wafer prober 12 as a prober mechanism, a tester 16 for conducting an electrical test of a semiconductor wafer 14 supported by the wafer prober, and a probe assembly 18 for electrically connecting the tester to the semiconductor wafer 14, as shown in FIG. 1.

The wafer prober 12 comprises an entirely rectangular casing 20 and a chuck top 24 held on a test stage 22 arranged in the casing. The semiconductor wafer 14 has numerous integrated circuits incorporated therein and is removably held on the chuck top 24 with their electrodes directing upward. The test stage 22 is combination of X, Y, Z, and theta stages as is conventionally well known, and the chuck top 24 enables positional adjustment in an X direction and a Y direction perpendicular to this on the horizontal plane, in a vertical direction (Z direction) perpendicular to the horizontal plane (XY plane), and in a rotating direction (theta) around the Z axis.

The probe assembly 18 comprises a probe card 26 and a support member 28 supporting the probe card. The probe card 26 comprises a circular probe board 26a and numerous probes 26b provided on one surface 30a of the probe board.

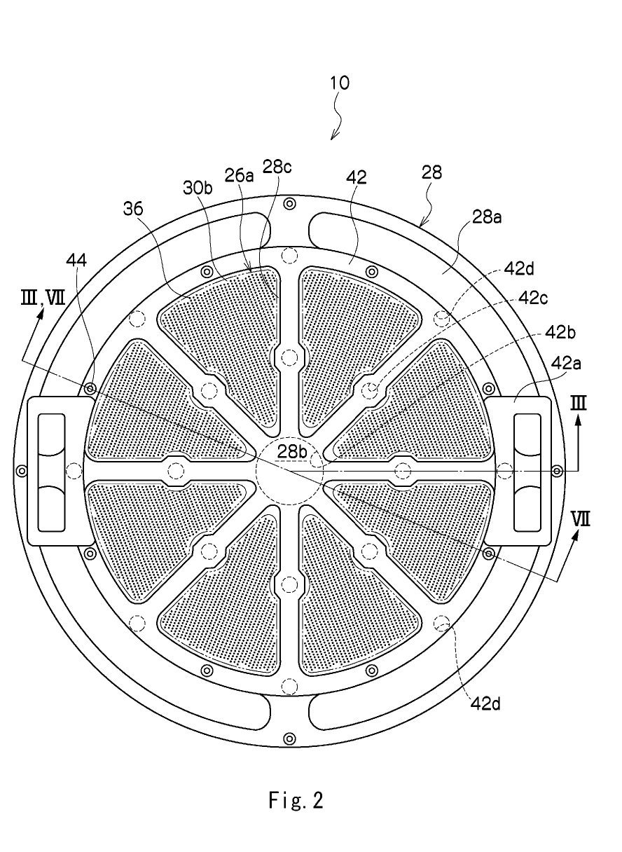

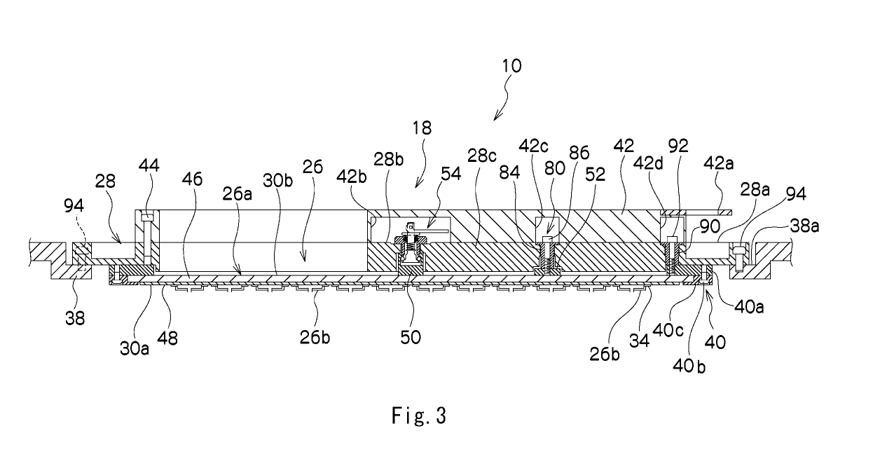

In the probe board 26a, wiring paths 32 similar to conventional ones are provided. One edge of each wiring path 32 is terminated at a probe land 34 (refer to FIG. 3) provided on one surface 30a of the probe board 26a while the other edge is terminated at a tester land 36 (refer to FIG. 2) provided on the other surface 30b of the probe card 26. Each probe 26b is fixed to each probe land 34, and thus each probe 26b is electrically connected to the corresponding probe land 34.

The probe card 26 is held by an annular card holder 38 held at the top portion of the casing 20 of the wafer prober 12 via the support member 28 to which the probe board 26a is attached. In this manner, the probe card 26 is held so that its probes 26b are opposed to the semiconductor wafer 14 on the chuck top 24. Also, in the example shown in the figures, the edge portion of the probe board 26a is supported by the support member 28 via an annular support structure 40.

On the upper side of the probe assembly 18 held by the card holder 38, a tester head 16a connected to a not shown tester main body of the tester 16 is swingably supported by the casing 20 via a not shown arm so as to be electrically connected to the probe assembly 18.

The support member 28 is made of an entirely plate-shaped member such as a stainless plate as shown in FIGS. 2 and 3. This support member 28 comprises an annular rim portion 28a having a larger outer diameter than that of the probe board 26a, an entirely circular boss portion 28b formed concentrically with the rim portion, and a spoke portion 28c extending radially from the boss portion and coupling the boss portion 28b with the rim portion 28a, as clearly shown in FIG. 2.

The aforementioned tester lands 36 of the probe board 26a are arranged in a concentrated manner at areas exposed from the support member 28 between the rim portion 28a and the boss portion 28b on 30b of the probe board 26a.

In the example shown in the figures, a cover 42 covering the inner edge of the rim portion 28a, the boss portion 28b and the spoke portion 28c is removably mounted on the support member 28 via bolts 44 so as not to prevent exposure of the tester lands 36. On the cover 42 are formed a pair of knobs 42a to facilitate handling of the probe assembly 18.

In the example shown in FIG. 3, the probe board 26a has an insulating plate 46 such as a ceramic plate and a multilayer wiring layer 48 fixed on the lower surface of the insulating plate. The insulating plate 46 has the aforementioned tester lands 36 on the upper surface constituting the other surface 30b of the probe board 26a. In the insulating plate 46, a wiring path part constituting a part of each aforementioned wiring path 32 extends from the tester land 36 to pass through the insulating plate 46 in its plate thickness direction, although not shown in the figure. The multilayer wiring layer 48 has the aforementioned probe lands 34 for the probe board 26a on the lower surface constituting one surface 30a of the probe board 26a. Also, in the multilayer wiring layer 48 is formed a wiring path part extending from each probe land 34, connected to the aforementioned wiring path part of the insulating plate 46, and constituting the wiring path 32 together with the wiring path part, although not shown in the figure. In this manner, the probe 26b fixed to each probe land 34 is electrically connected to the corresponding tester land 36.

On the aforementioned upper surface of the insulating plate 46 or the other surface 30b of the probe board 26a are provided coupling portions 50, 52 to be coupled with the support member 28. The coupling portion 50 is arranged at the center of the probe board 26a while the coupling portions 52 are arranged on the peripheral portions. In relation to the coupling portion 50 at the center, a lock mechanism 54 is provided.

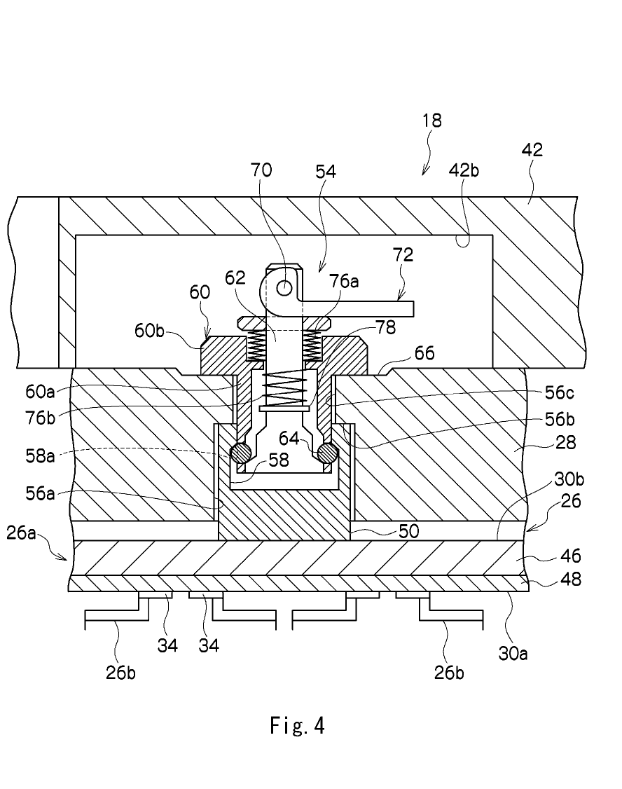

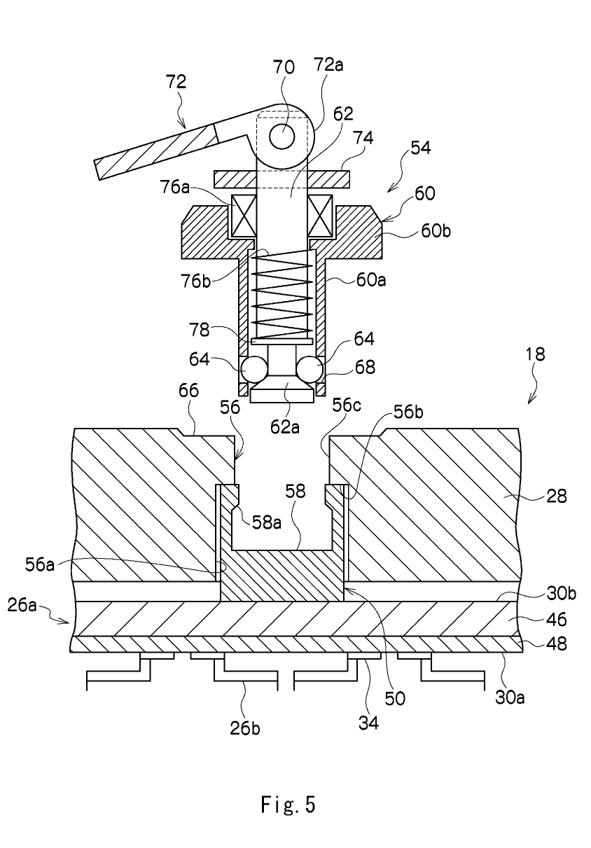

The lock mechanism 54 is incorporated in a central through hole 56 formed in the support member 28 as shown in FIGS. 4 and 5. This through hole 56 has a large-diameter portion 56a located on the lower surface side of the support member 28 and a small-diameter portion 56c located at the upper surface side and communicating with the large-diameter portion 56a via a shoulder portion 56b.

The bottom surface of the coupling portion 50 is fixed to the insulating plate 46, the coupling portion 50 stands up from the insulating plate into the large-diameter portion 56a, and its top portion can abut to a shoulder portion 56b. As clearly shown in FIG. 5, in the coupling portion 50 is formed a recess 58 opened at its top portion, and in the vicinity of the opening of the recess is formed a shoulder portion 58a comprising a narrow portion whose diameter gradually decreases.

The lock mechanism 54 comprises a lock holder member 60 having a cylindrical portion 60a that can be inserted from the upper surface side of the support member 28 into the recess 58 of the coupling portion 50 via the small-diameter portion 56c of the through hole 56 and a flange portion 60b formed at one edge of the cylindrical portion, a lock shaft 62 arranged in the lock holder member 60 along the axial direction of the lock holder member, and spherical lock members 64 that can be operated by the lock shaft.

The flange portion 60b of the lock holder member 60 can abut on a seat surface 66 formed on the upper surface of the support member 28. Also, the lower edge of the lock holder member 60 can extend into the recess 58, and in the vicinity of the lower edge of the lock holder member 60 are formed openings 68 allowing partial protrusion of the lock members 64.

The upper edge of the lock shaft 62 is protruded from the lock holder member 60, and at the protruded edge, a cam lever 72 is pivotally provided via an axis 70. On the cam lever 72 is formed a cam surface 72a that moves the lock holder member 60 in its axis direction by the swinging operation of the cam lever 72 around the axis 70, and the cam surface slides on a washer 74 over the flange portion 60b by the swinging of the cam lever 72. At the lower edge portion of the lock shaft 62 is formed a sloped surface 62a holding the lock members 64 and letting part of each lock member 64 protruded outward from the opening 68 when the lock shaft 62 is pulled upward.

Between the washer 74 and the flange portion 60b of the lock holder member 60 is arranged a first compression coil spring 76a so as to surround the lock shaft 62. Also, between an E ring 78 locked by the lock shaft and the flange portion 60b is arranged a second compression coil spring 76b so as to surround the lock shaft 62. The first compression coil spring 76a presses the washer 74 to the cam surface 72a of the cam lever 72. Also, the second compression coil spring 76b presses down the lock shaft 62 in relation to the lock holder member 60.

When the cam lever 72 is in a release position shown in FIG. 5, the lock shaft 62 is held in a lower edge position by a spring force of the second compression coil spring 76b. In the lower edge position, the sloped surface 62a at the lower edge will not let the lock members 64 protruded from the openings 68 of the lock holder member 60. Thus, in this state, the cylindrical portion 60a of the lock holder member 60 can be inserted in the recess 58 of the coupling portion 50.

Under this insertion state, when the cam lever 72 is swung toward a lock position shown in FIG. 4, overcoming the spring forces of the both compression coil springs 76a, 76b, the lock shaft 62 is pulled up in relation to the lock holder member 60 by the cam surface 72a of the cam lever 72, and thus the sloped surface 62a of the lock shaft 62 presses the lock members 64 to the shoulder portion 58a of the coupling portion 50. As a result, since the edge portion of the small-diameter portion 56c of the support member 28 is sandwiched between the coupling portion 50 of the probe board 26a and the flange portion 60b of the lock mechanism 54, the probe card 26 is coupled with the support member 28 at its center part. Also, in this coupling state, by a spacer function of the lock holder member 60 and the coupling portion 50, the distance from the support member 28 to one surface 30a of the probe board 26a is kept to be a predetermined distance, as shown in FIG. 4. Thus, the tips of the probes 26b are held in a predetermined flat height position.

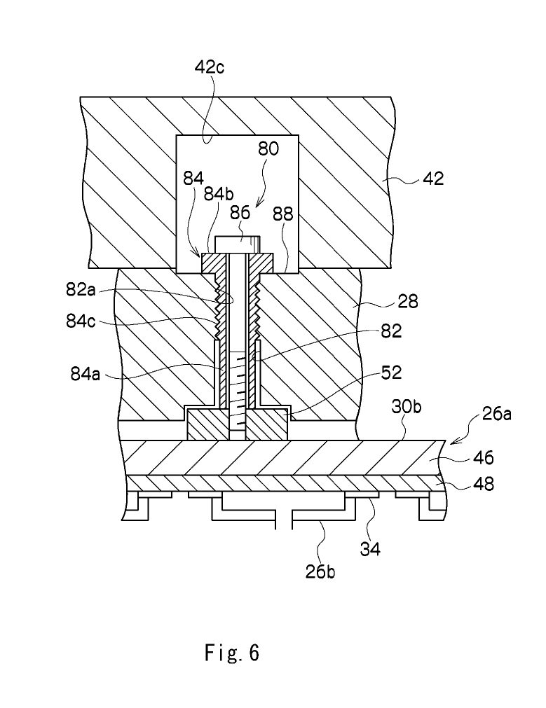

Each of the coupling portions 52 arranged on the periphery of the coupling portion 50 is formed by a female screw member fixed on the other surface 30b of the probe board 26a or the aforementioned upper surface of the insulating plate 46 as shown in FIG. 6. In relation to each coupling portion 52, a screw coupling mechanism 80 is provided.

The screw coupling mechanism 80 comprises a cylindrical spacer 84 inserted in a through hole 82 formed in the support member 28 and a bolt member 86 that is inserted in the spacer and whose tip edge portion can be screwed in a screw hole 52a of the coupling portion 52. On the aforementioned upper surface of the support member 28 is formed a seat surface 88 surrounding the through hole 82, and in the vicinity of the seat surface 88 on the inner surface of the through hole 82 are formed female screw grooves 82a.

The spacer 84 comprises a cylindrical portion 84a inserted in the through hole 82 and a flange portion 84b formed at the upper edge of the cylindrical portion and mounted on the aforementioned seat surface 88 of the support member 28. On the upper half portion of the cylindrical portion 84a are formed male screw grooves 84c that can be screwed together with the female screw grooves 82a.

As for the spacer 84, the lower edge of the cylindrical portion 84a can be inserted in the through hole 82 from the upper surface side of the support member 28, its male screw grooves 84c are screwed with the female screw grooves 82a to tighten the spacer 84 in the support member 28, and the flange portion 84b can abut on the seat surface 88. When the tip edge portion of the bolt member 86 inserted in the spacer 84 is tightened in the coupling portion 52 in a state where the spacer 84 is tightened in the support member 28, the lower edge of the cylindrical portion 84a of the spacer 84 abuts to the coupling portion 52. By a spacer function of this spacer and the coupling portion 52, the distance from the support member 28 to one surface 30a of the probe board 26a is kept to be a predetermined distance, as in a similar manner to that of the lock mechanism 54. Thus, the tips of the probes 26b are held in the aforementioned predetermined flat height position.

The aforementioned annular support structure 40 holding the edge portion of the probe board 26a has an annular base member 40a and a fixing ring 40c coupled with the base member 40a via a screw member 40b screwed in the base member 40a for the purpose of sandwiching the edge portion of the probe board 26a between the annular base member 40a and the fixing ring 40c, in the example shown in FIG. 3. The base member 40a is fixed on the lower surface of the support member 28 via a spacer 90 and a bolt member 92 screwed in the support member 28 and having a similar spacer function to that in the screw coupling mechanism 80.

The probe card 26 having the probe board 26a and the probes 26b is coupled with the support member 28 by the aforementioned lock mechanism 54, screw coupling mechanisms 80 and annular support structure 40. Thereafter, a cover 42 is fixed on the support member 28 with bolts 44 so as to cover the lock mechanism 54, screw coupling mechanisms 80 and annular support structure 40 for the purpose of housing their parts protruded from the support member 28 in respective recesses 42b, 42c, 42d. By mounting of this cover 42, variation in height positions of the probe tips caused by erroneous operations of the lock mechanism 54, the screw coupling mechanisms 80, etc. can be prevented.

As for the probe assembly 18 covered with the cover 42, the outer edge of the rim portion 28a projecting outward from the probe board 26a in its radius direction is mounted on a step portion 38a of the card holder 38 and is fixed on the card holder 38 with screw members 94, as shown in FIG. 3.

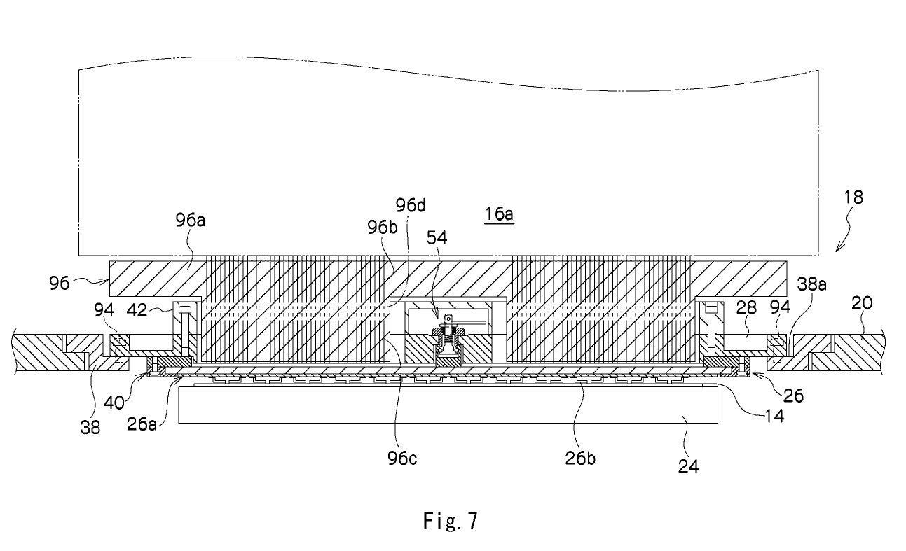

After attachment to the card holder 38, a connection portion 96 of the tester head 16a is connected to the probe card 26, as shown in FIG. 7. The connection portion 96 is a conventionally well-known pogo pin assembly in the example shown in the figures. The pogo pin assembly 96 comprises a pogo pin block 96a fixed to the tester head 16a, needle member pairs 96b, 96c arranged in series in respective guide holes formed to penetrate the pogo pin block in the thickness direction, and conductive spring members 96d such as compression coil springs each arranged between the needle members and electrically connecting the needle members to each other.

The tip end of one needle member 96b protruded from the pogo pin block 96a in each needle member pair 96b, 96c is thrust to a corresponding conductive path (not shown) of the tester head 16a by a spring force of the spring member 96d. Also, the tip end of the other needle member 96c protruded from the pogo pin block 96a is thrust to the corresponding tester land 36 of the probe board 26a by a spring force of the spring member 96d so as to be electrically connected to the tester land 36.

Each tester land 36 is provided at one terminal of each wiring path 32 provided in the probe board 26a of the probe card 26. Thus, when each probe 26a provided at the other terminal of this wiring path 32 contacts each corresponding electrode pad of the semiconductor wafer 14 on the chuck top 24, the aforementioned tester main body of the test apparatus 10 and the device under test 14 are electrically connected to each other via the probe 26b and the wiring path 32, and an electrical test of the device under test is conducted.

In the test apparatus 10 according to the present invention, the connection portion 96 (needle member 96c) of the tester head 16a is directly connected to each wiring path 32 of the probe card 26 without passing through a wiring board and an electrical connecting apparatus inserted between the wiring board and a probe card as in a conventional case.

Accordingly, these conventional wiring board and electrical connecting apparatus are not needed, and the constitutions of the probe assembly 18 and also the test apparatus 10 can be simplified. Also, since the wiring board and electrical connecting apparatus are not needed, the circuits from the probes 26b of the probe card 26 to the connection portion 96 of the tester head 16a are constituted by the wiring paths 32 of the probe board 26a, and also the tester lands 36 can be arranged inside the rim portion 28a of the support member 28 in a concentrated manner. Thus, the circuit length can be much shortened than the circuit length of a conventional test apparatus requiring the wiring board and the electrical connecting apparatus. By the shortening of the circuit length, it is possible to restrict interference of noise with high-frequency test signals flowing in the circuits having the circuit length. Consequently, resistance to noise is significantly improved, and thus accuracy of the electrical test using these high-frequency signals is largely heightened.

The present invention is not limited to the above embodiments but may be altered in various ways without departing from the spirit and scope of the present invention. As a connection portion of the tester head in the test apparatus, various kinds of contactors that can contact the tester lands, such as a needle member, can be applied instead of the aforementioned pogo pin assembly.

What is claimed is:

1. A semiconductor test apparatus for use in an electrical test of a semiconductor wafer in which numerous integrated circuits each having electrode pads are incorporated, comprising:
a probe card having a probe board having on one surface numerous probes that can be connected to said electrode pads of said semiconductor wafer, having on the other surface tester lands corresponding to said probes, and having wiring paths each connecting said probe and said tester land corresponding to each other; and
a tester provided with a connection portion that can contact said tester lands.

2. The semiconductor test apparatus according to claim 1, wherein on said one surface of said probe board are provided probe lands connected to said corresponding tester lands via said wiring paths, and said probes are connected to said probe lands.

3. The semiconductor test apparatus according to claim 1, further comprising a prober mechanism, wherein said prober mechanism has a casing and a test stage provided with a chuck that holds said semiconductor wafer in said casing, at the upper portion of said casing is provided an annular card holder for holding said probe board, on said the other surface of said probe board is provided a support member provided with an edge portion projecting from an edge portion of said probe board and mounted on said card holder, and said probe card is supported by said card holder via said support member so that said probes can abut on said electrode pads of said semiconductor wafer on said chuck.

4. The semiconductor test apparatus according to claim 3, wherein said support member has an annular rim portion having said edge portion mounted on said card holder, a boss portion located at the center of the annulus of said annular portion, and spoke portions coupling said boss portion with said rim portion.

5. The semiconductor test apparatus according to claim 4, wherein said tester lands are arranged at areas exposed from said support member on said the other surface of said probe board.

6. The semiconductor test apparatus according to claim 5, wherein said tester lands are arranged inside said annular rim portion.

7. The semiconductor test apparatus according to claim 1, wherein said probe board consists of a ceramic plate and a multilayer wiring layer fixed on one surface of said ceramic plate, said wiring path of said probe board consists of a wiring path part formed to pass through said ceramic plate in its plate thickness direction and a wiring path part of said multilayer wiring layer connected to said wiring path part, said tester lands are formed on the other surface of said ceramic plate, and said probes are fixed on an opposite surface of a surface of said multilayer wiring layer fixed to said ceramic plate.

8. The semiconductor test apparatus according to claim 1, wherein said connection portion of said tester comprises a pogo pin assembly fixed to a tester head.
